(19) United States
(12) Patent Application Publication
(10) Pub. No.: US 2024/0179979 A1
(43) Pub. Date: May 30, 2024

(54) DISPLAY APPARATUS

(71) Applicant: Samsung Display Co., Ltd., Yongin-si, Gyeonggi-do (KR)

(72) Inventor: Inyoung Jung, Yongin-si, Gyeonggi-do (KR)

(73) Assignee: Samsung Display Co., Ltd., Yongin-si, Gyeonggi-do (KR)

(21) Appl. No.: 18/464,342

(22) Filed: Sep. 11, 2023

(30) Foreign Application Priority Data
Nov. 28, 2022 (KR) 10-2022-0162029

(51) Int. Cl. H10K 59/131; H10K 59/122

(52) U.S. Cl. CPC H10K 59/131; H10K 59/122

(57) ABSTRACT

A display apparatus includes a substrate including a display area in which a plurality of pixels are arranged and a non-display area disposed adjacent to the display area, a pixel electrode disposed on the display area of the substrate, a metal bank layer disposed in the display area and the non-display area and defining a pixel opening exposing a portion of the pixel electrode and a hole spaced apart from the pixel opening and extending in a first direction, and a horizontal voltage line disposed in the display area inside the hole in a plan view.

### CROSS-REFERENCE TO RELATED APPLICATION(S)

This application claims priority to and benefits of Korean Patent Application No. 10-2022-0162029 under 35 U.S.C. § 119, filed on Nov. 28, 2022, in the Korean Intellectual Property Office (KIPO), the contents of which are incorporated herein by reference.

### BACKGROUND

### 1. Technical Field

The disclosure relates to a display apparatus.

### 2. Description of the Related Art

Applications of conventional display apparatuses have diversified. Also, due to their relatively small thickness and light weight, the application range thereof has increased.

Display apparatuses include a plurality of pixels that receive electrical signals and emit light to display an image to the outside. A pixel of an organic light-emitting display device (OLED) includes an organic light-emitting diode as a display element, and a driving circuit for controlling an electrical signal applied to the display element. The driving circuit includes a thin-film transistor (TFT), a storage capacitor, and a plurality of lines. The plurality of lines provide data signals, driving voltages, and common voltages to the driving circuit of each pixel.

### SUMMARY

However, such a conventional display apparatus has a problem in that a luminance difference depending on the location of a pixel occurs due to resistance of lines that supply a driving voltage or a common voltage.

The disclosure includes a display apparatus that displays a high-quality image. However, aspects of embodiments are not limited thereto, and the above characteristics do not limit the scope of embodiments according to the disclosure.

Additional aspects will be set forth in portion in the description which follows and, in part, will be apparent from the description, or may be learned by practice of the presented embodiments of the disclosure.

According to an embodiment, a display apparatus may include a substrate including a display area in which a plurality of pixels are arranged and a non-display area disposed adjacent to the display area, a pixel electrode disposed on the display area of the substrate, a metal bank layer disposed in the display area and the non-display area and defining a pixel opening exposing a portion of the pixel electrode and a hole spaced apart from the pixel opening and extending in a first direction, and a horizontal voltage line disposed in the display area inside the hole in a plan view.

The metal bank layer may include a first sub-metal layer and a second sub-metal layer disposed on the first sub-metal layer, and the second sub-metal layer may have a tip extending from an upper surface of the first sub-metal layer toward a center of the pixel opening.

The display apparatus may further include an intermediate layer disposed on the pixel electrode in the pixel opening, and an opposite electrode disposed on the intermediate layer in the pixel opening.

The opposite electrode may be directly connected to the first sub-metal layer.

The display apparatus may further include a common power supply line disposed in the non-display area and surrounding at least a portion of the display area in a plan view. The first sub-metal layer may be directly connected to the common power supply line.

The metal bank layer may have a first boundary and a second boundary facing the first boundary, and the first boundary and the second boundary may overlap the common power supply line in a plan view.

The horizontal voltage line may have a first end and a second end, and the first end and the second end of the horizontal voltage line may be disposed between the first boundary and the second boundary of the metal bank layer.

The horizontal voltage line may include a first horizontal line and a second horizontal line disposed on the first horizontal line, the first horizontal line and the first sub-metal layer may include a same material, and the second horizontal line and the second sub-metal layer may include a same material.

The display apparatus may further include a driving voltage line disposed between the substrate and the horizontal voltage line and extending in a second direction intersecting the first direction. The horizontal voltage line may be electrically connected to the driving voltage line.

The driving voltage line may include a plurality of driving voltage lines, and the horizontal voltage line may include a plurality of horizontal voltage lines. In a plan view, the plurality of driving voltage lines and the plurality of horizontal voltage lines may form a mesh shape.

According to an embodiment, a display apparatus includes a substrate including a display area in which a plurality of pixels are arranged and a non-display area disposed adjacent to the display area, a pixel electrode disposed on the display area of the substrate, a metal bank layer disposed in the display area and the non-display area and defining a pixel opening exposing a portion of the pixel electrode and a first sub-hole and a second sub-hole spaced apart from the pixel opening, each of the first sub-hole and the second sub-hole extending in a first direction, and a horizontal voltage line disposed in the display area and the non-display area between the first sub-hole and the second sub-hole in a plan view.

The metal bank layer may include a first sub-metal layer and a second sub-metal layer disposed on the first sub-metal layer, and the second sub-metal layer may have a tip extending from an upper surface of the first sub-metal layer toward a center of the pixel opening.

The display apparatus may further include an intermediate layer disposed on the pixel electrode in the pixel opening, and an opposite electrode disposed on the intermediate layer in the pixel opening.

The opposite electrode may be directly connected to the first sub-metal layer.

The display apparatus may further include a common power supply line disposed in the non-display area and surrounding at least a portion of the display area in a plan view. The first sub-metal layer may be directly connected to the common power supply line.

The metal bank layer may have a first boundary and a second boundary facing the first boundary, and the first boundary and the second boundary may overlap the common power supply line in a plan view.

The horizontal voltage line may have a first end and a second end. The first end of the horizontal voltage line may be colinear with the first boundary of the metal bank layer, and the second end of the horizontal voltage line may be colinear with the second boundary of the metal bank layer.

The horizontal voltage line may include a first horizontal line and a second horizontal line disposed on the first horizontal line, the first horizontal line and the first sub-metal layer may include a same material, and the second horizontal line and the second sub-metal layer may include a same material.

The display apparatus may further include a driving voltage line disposed between the substrate and the horizontal voltage line and extending in a second direction intersecting the first direction. The horizontal voltage line may be electrically connected to the driving voltage line.

The driving voltage line may include a plurality of driving voltage lines and the horizontal voltage line may include a plurality of horizontal voltage lines. In a plan view, the plurality of driving voltage lines and the plurality of horizontal voltage lines may form a mesh shape.

These and/or other aspects will become apparent and more readily appreciated from the following description of the embodiments, taken in conjunction with the accompanying drawings.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a schematic plan view of a display panel included in a display apparatus according to an embodiment;

FIG. 3A is a schematic diagram of an equivalent circuit of a pixel included in display apparatuses according to an embodiment;

FIG. 3B is a schematic diagram of an equivalent circuit of a pixel included in display apparatuses according to an embodiment;

FIG. 4 is a schematic plan view of a portion of a display panel according to an embodiment;

FIG. 5 is a schematic plan view of a portion of a display panel according to an embodiment;

FIG. 6 is a schematic plan view of a portion of a display panel according to an embodiment;

FIG. 7 is a schematic plan view of a portion of a display panel according to an embodiment;

FIG. 8 is a schematic plan view of a portion of a display panel according to an embodiment; and

FIG. 9A is a schematic cross-sectional view of a portion of a display panel according to an embodiment;

FIG. 9B is a schematic cross-sectional view of a portion of a display panel according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

As the disclosure allows for various changes and numerous embodiments, particular embodiments will be illustrated in the drawings and described in detail in the written description. Hereinafter, effects and features of the disclosure and a method for accomplishing them will be described more fully with reference to the accompanying drawings, in which embodiments of the disclosure are shown. The disclosure may, however, be embodied in many different forms and should not be construed as limited to the embodiments set forth herein.

Embodiments will be described below in more detail with reference to the accompanying drawings. Those components that are the same as or are in correspondence with each other are rendered the same reference numeral regardless of the figure number, and redundant explanations are omitted.

It will be understood that although the terms “first,” “second,” etc. may be used herein to describe various components, these components should not be limited by these terms. These components are only used to distinguish one component from another.

As used herein, the singular forms “a,” “an,” and “the” are intended to include the plural forms as well, unless the context clearly indicates otherwise.

The terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

When a layer, region, or component is referred to as being “formed on” another layer, region, or component, it can be directly or indirectly formed on the other layer, region, or component. For example, intervening layers, regions, or components may be present.

When a layer, region, or component is referred to as being “connected” or “coupled” to another layer, region, or component, it can be directly connected or coupled to the other layer, region, or/and component or intervening layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

In the following examples, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

Sizes of elements in the drawings may be exaggerated or reduced for convenience of explanation. For example, since sizes and thicknesses of components in the drawings are arbitrarily illustrated for convenience of explanation, embodiments are not limited thereto.

It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

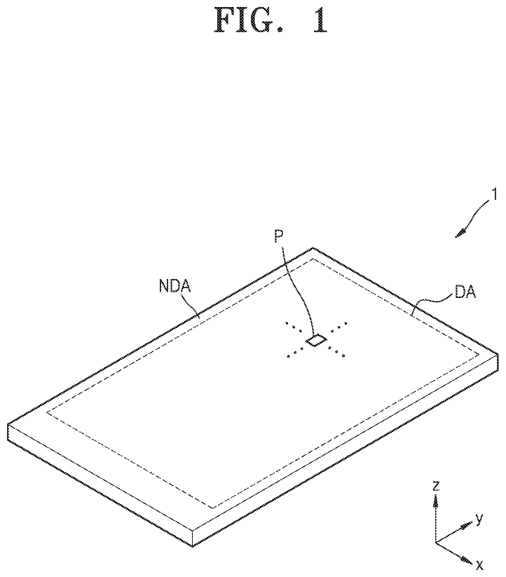

FIG. 1 is a schematic perspective view of a display apparatus 1 according to an embodiment.

Referring to FIG. 1, the display apparatus 1 may include a display area DA and a non-display area NDA adjacent to the display area DA. The display area DA may display an image through pixels P arranged in the display area DA. The non-display area NDA may be located adjacent to the display area DA and does not display an image, and may surround the entirety of the display area DA. A driver or the like for providing an electrical signal or power to the display area DA may be disposed in the non-display area NDA. A pad that is an area where an electronic device or a printed circuit board (PCB) may be electrically connected may be disposed in the non-display area NDA.

According to an embodiment, FIG. 1 illustrates that the display area DA is a polygon (e.g., a quadrangle) of which a length in an x direction is less than a length in a y direction in a plan view. However, the disclosure is not limited thereto. In another embodiment, the display area DA may have other shapes such as an N-gon (where N is a natural number equal to or greater than 3), a circle, or an ellipse. In FIG. 1, each of the corners of the display area DA may include a vertex where straight lines meet each other. However, in another embodiment, the display area DA may be a polygon with rounded corners in a plan view.

A case in which the display apparatus 1 is an electronic device that is a smartphone will now be described for convenience of description, but the display apparatus 1 of the disclosure is not limited thereto. The display apparatus 1 may be applicable to not only portable electronic apparatuses, such as mobile phones, smartphones, tablet personal computers (PCs), mobile communication terminals, electronic notebooks, electronic books, portable multimedia players (PMPs), navigation devices, and ultra mobile PCs (UMPCs), but also to various products, such as televisions, notebooks, monitors, advertisement panels, and Internet of things (IoT) devices. The display apparatus 1 according to an embodiment may be also applicable to wearable devices, such as smart watches, watch phones, glasses-type displays, and head mounted displays (HMDs). The display apparatus 1 according to an embodiment may be also applicable to dashboards of automobiles, center information displays (CIDs) of the center fasciae or dashboards of automobiles, room mirror displays that replace the side mirrors of automobiles, and displays arranged on the rear sides of front seats to serve as entertainment devices for back seat passengers of automobiles.

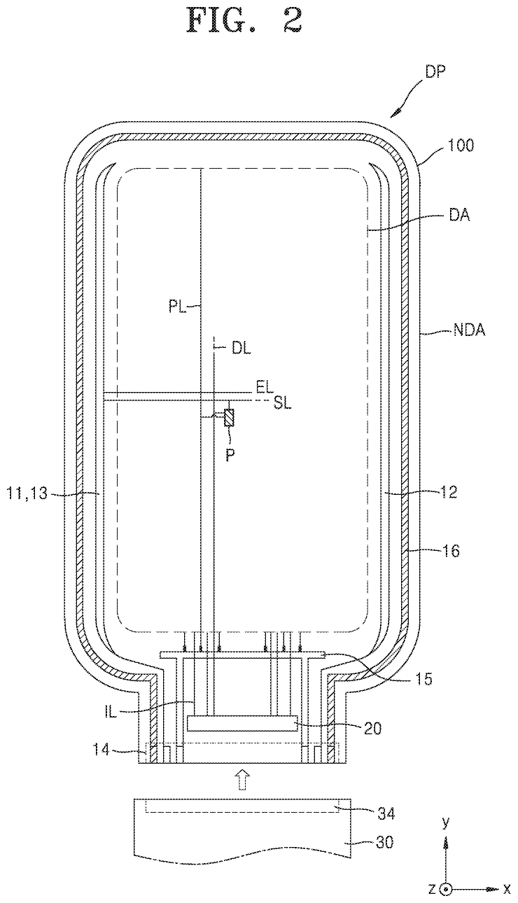

FIG. 2 is a schematic plan view of a display panel DP included in a display apparatus according to an embodiment.

Referring to FIG. 2, the display panel DP may include a display area DA and a non-display area NDA adjacent to the display area DA. The display area DA may be an area for displaying an image, and multiple pixels P may be arranged in the display area DA. Although FIG. 2 illustrates that the display area DA has a shape of a rectangle having approximately rounded corners in a plan view, the disclosure is not limited thereto. As described above, the display area DA may have various shapes such as an N-gon (where N is a natural number equal to or greater than 3), a circle, or an ellipse.

Each of the pixels P may be a subpixel and may include a display element, such as an organic light-emitting diode (OLED). The pixel P may emit, for example, red light, green light, blue light, or white light.

The non-display area NDA may be disposed adjacent to the display area DA. Outer circuits for driving the pixels P may be arranged in the non-display area NDA. For example, a first scan driving circuit 11, a second scan driving circuit 12, an emission control driving circuit 13, a terminal 14, a driving power supply line 15, and a common power supply line 16 may be arranged in the non-display area NDA.

The first scan driving circuit 11 may provide a scan signal to the pixel P via a scan line SL. The second scan driving circuit 12 may be disposed parallel to the first scan driving circuit 11 with the display area DA disposed between the first scan driving circuit 11 and the second scan driving circuit 12. Some of the pixels P arranged in the display area DA may be electrically connected to the first scan driving circuit 11, and the remaining ones of the pixels P may be connected to the second scan driving circuit 12. In an embodiment, the second scan driving circuit 12 may be omitted, and all of the pixels P disposed in the display area DA may be electrically connected to the first scan driving circuit 11.

The emission control driving circuit 13 may be disposed adjacent to the first scan driving circuit 11 and may provide an emission control signal to the pixel P via an emission control line EL. Although FIG. 2 illustrates that the emission control driving circuit 13 is disposed on only a side of the display area DA, the disclosure is not limited thereto. In an embodiment, the emission control driving circuit 13 may be disposed on both sides of the display area DA, similar to the first scan driving circuit 11 and the second scan driving circuit 12.

A driving chip 20 may be disposed in the non-display area NDA. The driving chip 20 may include an integrated circuit for driving the display panel DP. The integrated circuit may be a data driving integrated circuit for generating a data signal; however, the disclosure is not limited thereto.

The terminal 14 may be disposed in the non-display area NDA. The terminal 14 may be exposed without being covered by an insulating layer, and may be electrically connected to a PCB 30. A terminal 34 of the PCB 30 may be electrically connected to the terminal 14 of the display panel DP.

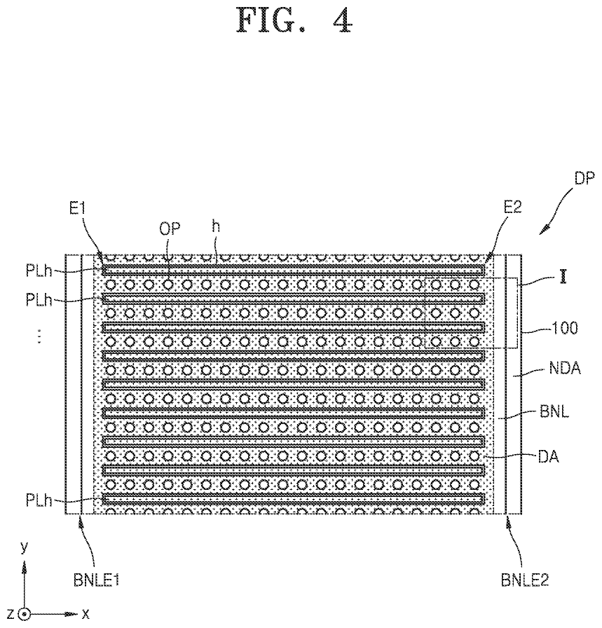

The PCB 30 may transmit a signal or power of a controller (not shown) to the display panel DP. A control signal generated by the controller may be transmitted to each of driving circuits via the PCB 30. The controller may transmit a driving voltage ELVDD to the driving power supply line 15 and provide a common voltage ELVSS to the common power supply line 16. The driving voltage ELVDD may be transmitted to each of the pixels P via a driving voltage line PL connected to the driving power supply line 15, and the common voltage ELVSS may be transmitted to an opposite electrode of each of the pixels P via a metal bank layer BNL (see FIG. 4) connected to the common power supply line 16. The driving power supply line 15 may have a shape extending in a direction (e.g., the x direction) on the lower side of the display area DA. The common power supply line 16 may partially surround the display area DA by having a loop shape of which one side is open in a plan view.

The controller may generate a data signal, and the generated data signal may be transmitted to an input line IL via the driving chip 20 and may be transmitted to a data line DL connected to the input line IL. For reference, the term ‘line’ may refer to ‘wiring’. This is equally applied to embodiments to be described below and modifications thereof.

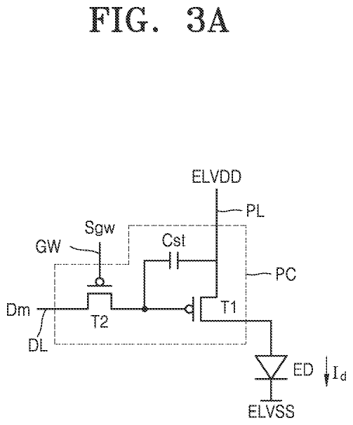

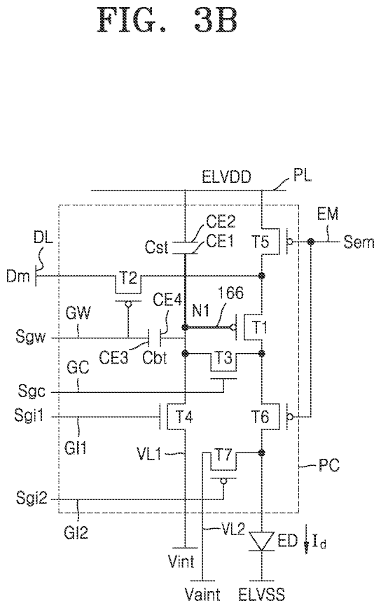

FIGS. 3A and 3B are schematic diagrams of equivalent circuits of a pixel included in display apparatuses according to embodiments.

Referring to FIG. 3A, a light-emitting diode ED may be electrically connected to a pixel circuit PC, and the pixel circuit PC may include a first transistor T1, a second transistor T2, and a storage capacitor Cst.

The second transistor T2 may transmit, to the first transistor T1, a data signal Dm received via the data line DL in response to a scan signal Sgw received via a scan line GW. The scan line GW may be same as the scan line SL in FIG. 2.

The storage capacitor Cst may be connected to the second transistor T2 and the driving voltage line PL, and may store a voltage corresponding to a difference between a voltage received from the second transistor T2 and the driving voltage ELVDD supplied from the driving voltage line PL.

The first transistor T1 may be connected to the driving voltage line PL and the storage capacitor Cst, and may control a driving current Id flowing from the driving voltage line PL to the light-emitting diode ED, in accordance with a voltage value stored in the storage capacitor Cst. An opposite electrode (for example, a cathode) of the light-emitting diode ED may receive the common voltage ELVSS. The light-emitting diode ED may emit light having a certain brightness by the driving current Id.

Although a case where the pixel circuit PC includes two transistors and one storage capacitor is illustrated in FIG. 3A, the disclosure is not limited thereto.

Referring to FIG. 3B, the pixel circuit PC may include seven transistors and two capacitors.

The pixel circuit PC may include first, second, third, fourth, fifth, sixth, and seventh transistors T1, T2, T3, T4, T5, T6, and T7, a storage capacitor Cst, and a boost capacitor Cbt. According to another embodiment, the pixel circuit PC may not include the boost capacitor Cbt.

Some of the first, second, third, fourth, fifth, sixth, and seventh transistors T1, T2, T3, T4, T5, T6, and T7 may be n-channel metal oxide semiconductor (NMOS) transistors, e.g., NMOS field effect transistors (N-MOSFETs), and others of the first, second, third, fourth, fifth, sixth, and seventh transistors T1, T2, T3, T4, T5, T6, and T7 may be p-channel metal oxide semiconductor (PMOS) transistors, e.g., PMOS field effect transistors (P-MOSFETs). According to another embodiment, the third and fourth transistors T3, and T4 may be NMOS transistors, e.g., N-MOSFETs, and others may be PMOS transistors, e.g., P-MOSFETs.

The first, second, third, fourth, fifth, sixth, and seventh transistors T1, T2, T3, T4, T5, T6, and T7, the storage capacitor Cst, and the boost capacitor Cbt may be connected to signal lines. The signal lines may include a scan line GW, an emission control line EM, a compensation gate line GC, a first initialization gate line GI1, a second initialization gate line GI2, and a data line DL. The pixel circuit PC may be electrically connected to voltage lines, for example, a driving voltage line PL, a first initialization voltage line VL1, and a second initialization voltage line VL2.

The first transistor T1 may be a driving transistor. A first gate electrode of the first transistor T1 may be connected to the storage capacitor Cst, a first electrode of the first transistor T1 may be electrically connected to the driving voltage line PL via the fifth transistor T5, and a second electrode of the first transistor T1 may be electrically connected to a pixel electrode (e.g., an anode) of the light-emitting diode ED via the sixth transistor T6. One of the first electrode and the second electrode of the first transistor T1 may be a source electrode, and another one of the first electrode and the second electrode of the first transistor T1 may be a drain electrode. The first transistor T1 may supply the driving current Id to the light-emitting diode ED according to a switching operation of the second transistor T2.

The second transistor T2 may be a switching transistor. A second gate electrode of the second transistor T2 may be connected to the scan line GW, a first electrode of the second transistor T2 may be connected to the data line DL, and a second electrode of the second transistor T2 may be connected to the first electrode of the first transistor T1 and electrically connected to the driving voltage line PL via the fifth transistor T5. One of the first electrode and the second electrode of the second transistor T2 may be a source electrode, and another one of the first electrode and the second electrode of the second transistor T2 may be a drain electrode. The second transistor T2 may be turned on according to the scan signal Sgw received via the scan line GW and may perform a switching operation of transmitting the data signal Dm received through the data line DL to the first electrode of the first transistor T1.

The third transistor T3 may be a compensating transistor that compensates a threshold voltage of the first transistor T1. A third gate electrode of the third transistor T3 may be connected to the compensation gate line GC. A first electrode of the third transistor T3 may be connected to a lower electrode CE1 of the storage capacitor Cst and the first gate electrode of the first transistor T1 through a node connection line 166. A first electrode of the third transistor T3 may be connected to the fourth transistor T4. A second electrode of the third transistor T3 may be electrically connected to the pixel electrode (e.g., an anode) of the light-emitting diode ED via the sixth transistor T6 and connected to the second electrode of the first transistor T1. One of the first electrode and the second electrode of the third transistor T3 may be a source electrode, and another one of the first electrode and the second electrode of the third transistor T3 may be a drain electrode.

The third transistor T3 may be turned on according to a compensation signal Sgc received via the compensation gate line GC and electrically connect the first gate electrode and the second electrode (e.g., a drain electrode) of the first transistor T1 to each other, such that the first transistor T1 is diode-connected.

The fourth transistor T4 may be a first initializing transistor that initializes the first gate electrode of the first transistor T1. A fourth gate electrode of the fourth transistor T4 may be connected to the first initialization gate line GI1. A first electrode of the fourth transistor T4 may be connected to the first initialization voltage line VL1. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode, and another one of the first electrode and the second electrode of the fourth transistor T4 may be a drain electrode. The fourth transistor T4 may be turned on in response to a first initialization signal Sgi1 received through the first initialization gate line GI1, to perform an initialization operation of initializing the voltage of the first gate electrode of the first transistor T1 by transmitting a first initializing voltage Vint to the first gate electrode of the first transistor T1.

The fifth transistor T5 may be an operation control transistor. A fifth gate electrode of the fifth transistor T5 may be connected to the emission control line EM, a first electrode of the fifth transistor T5 may be connected to the driving voltage line PL, and a second electrode of the fifth transistor T5 may be connected to the first electrode of the first transistor T1 and the second electrode of the second transistor T2. One of the first electrode and the second electrode of the fifth transistor T5 may be a source electrode, and another one of the first electrode and the second electrode of the fifth transistor T5 may be a drain electrode.

The sixth transistor T6 may be an emission control transistor. A sixth gate electrode of the sixth transistor T6 may be connected to the emission control line EM, a first electrode of the sixth transistor T6 may be connected to the second electrode of the first transistor T1 and the second electrode of the third transistor T3, and a second electrode of the sixth transistor T6 may be electrically connected to a second electrode of the seventh transistor T7 and the pixel electrode (e.g., an anode) of the light-emitting diode ED. One of the first electrode and the second electrode of the sixth transistor T6 may be a source electrode, and another one of the first electrode and the second electrode of the sixth transistor T6 may be a drain electrode.

The fifth transistor T5 and the sixth transistor T6 may be simultaneously turned on according to an emission control signal Sem received via the emission control line EM, and thus, the driving voltage ELVDD may be transmitted to the light-emitting diode ED such that the driving current Id may flow in the light-emitting diode ED.

The seventh transistor T7 may be a second initializing transistor that initializes the pixel electrode (e.g., an anode) of the light-emitting diode ED. A seventh gate electrode of the seventh transistor T7 may be connected to the second initialization gate line GI2. A first electrode of the seventh transistor T7 may be connected to the second initialization voltage line VL2. The second electrode of the seventh transistor T7 may be connected to the second electrode of the sixth transistor T6 and the pixel electrode (e.g., an anode) of the light-emitting diode ED. The seventh transistor T7 may be turned on in response to a second initialization signal Sgi2 received through the second initialization gate line GI2, to initialize the pixel electrode (e.g., an anode) of the light-emitting diode ED by transmitting a second initializing voltage Vaint to the pixel electrode of the light-emitting diode ED.

In embodiments, the second initialization gate line GI2 may be a next scan line. For example, a second initialization gate line GI2 connected to a seventh transistor T7 of a pixel circuit PC disposed in an i-th row (where i is a natural number) may correspond to a scan line of a pixel circuit PC disposed in an (i+1)-th row. In another embodiment, the second initialization gate line GI2 may be an emission control line EM. For example, the emission control line EM may be electrically connected to the fifth, sixth, and seventh transistors T5, T6, and T7.

The storage capacitor Cst may include the lower electrode CE1 and an upper electrode CE2. The lower electrode CE1 of the storage capacitor Cst may be connected to the first gate electrode of the driving transistor T1, and the upper electrode CE2 of the storage capacitor Cst may be connected to the driving voltage line PL. The storage capacitor Cst may store a charge corresponding to a difference between the voltage of the first gate electrode of the first transistor T1 and the driving voltage ELVDD.

The boost capacitor Cbt may include a third electrode CE3 and a fourth electrode CE4. The third electrode CE3 may be connected to the second gate electrode of the second transistor T2 and the scan line GW, and the fourth electrode CE4 may be connected to the first electrode of the third transistor T3 and the node connection line 166. The boost capacitor Cbt may increase the voltage of a first node N1 in case that the scan signal Sgw supplied to the scan line GW is turned off, and, in case that the voltage of the first node N1 increases, black gradation may be clearly expressed.

The first node N1 may be a region to which the first gate electrode of the first transistor T1, the first electrode of the third transistor T3, the second electrode of the fourth transistor T4, and the fourth electrode CE4 of the boost capacitor Cbt are connected.

In an embodiment, FIG. 3B shows that the third and fourth transistors T3 and T4 are N-MOSFETs, and the first, second, fifth, sixth, and seventh transistors T1, T2, T5, T6, and T7 are P-MOSFETs. The first transistor T1 directly affecting the brightness of the display apparatus may include a semiconductor layer including polycrystal silicon having high reliability, and thus, a high-resolution display apparatus may be realized.

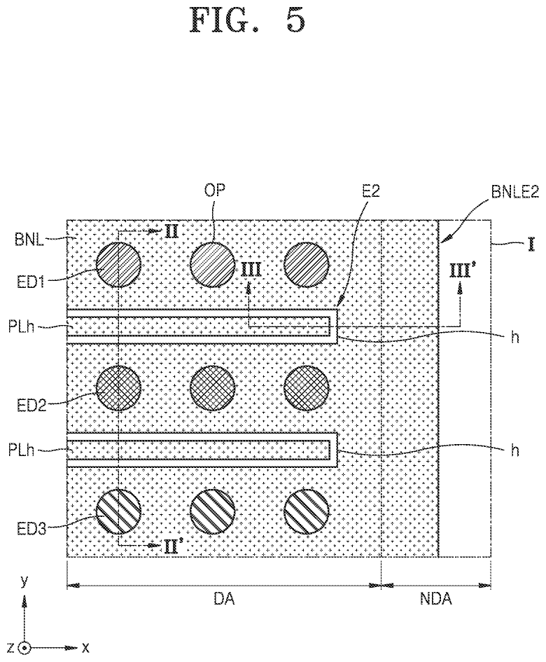

FIGS. 4 and 5 are schematic plan views of a portion of a display panel according to an embodiment. FIG. 4 is an enlarged view of a portion of the display panel DP shown in FIG. 2, and FIG. 5 is an enlarged view of portion I of FIG. 4.

Referring to FIGS. 4 and 5, the display panel DP may include a substrate 100. The substrate 100 may include a glass or a polymer resin. The substrate 100 may have a structure in which a base layer including a polymer resin and an inorganic barrier layer are stacked each other. The polymer resin may be polyethersulfone (PES), polyacrylate (PAR), polyetherimide (PEI), polyethylenen napthalate (PEN), polyethyleneterepthalate (PET), polyphenylene sulfide (PPS), polyarylate, polyimide (PI), polycarbonate (PC), cellulose triacetate (TAC), cellulose acetate propionate (CAP), or the like.

Components of the display panel DP may be disposed on the substrate 100, and the substrate 100 may have the display area DA displaying an image through the pixels P (see FIG. 1) and the non-display area NDA disposed adjacent to the display area DA.

First light-emitting diodes ED1, second light-emitting diodes ED2, third light-emitting diodes ED3, a horizontal voltage line PLh, and a metal bank layer BNL may be disposed on the substrate 100. For convenience of description, in FIG. 4, other components are omitted in order to explain a positional relationship between the metal bank layer BNL and the horizontal voltage line PLh.

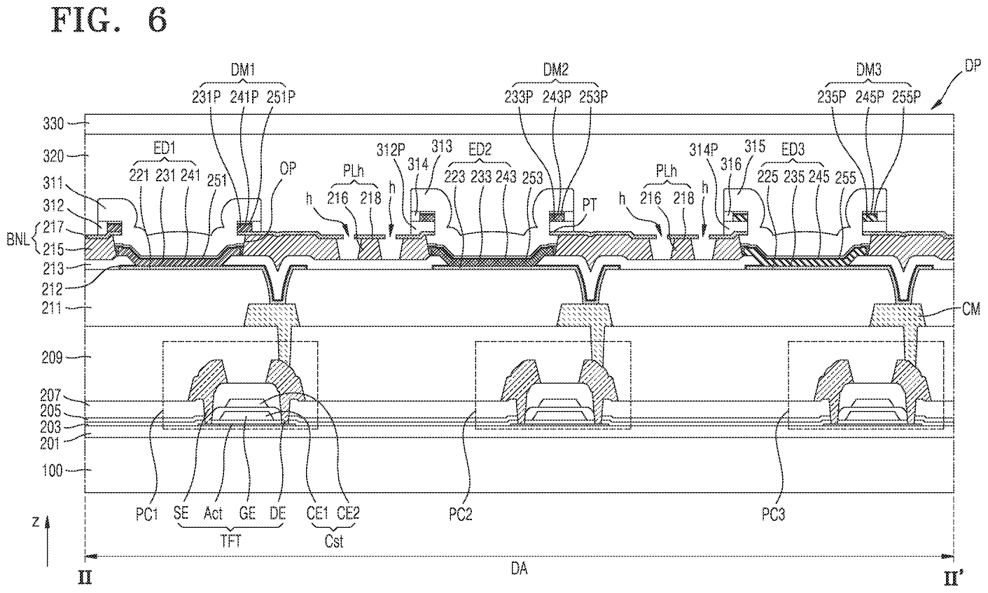

As will be described below, the metal bank layer BNL may include a first sub-metal layer 215 (see FIG. 6) and a second sub-metal layer 217 (see FIG. 6) including different metals.

The metal bank layer BNL may be disposed to cover the entire surface of the display area DA and a portion of the non-display area NDA. For example, the metal bank layer BNL may have a first boundary BNLE1 extending in a second direction (e.g., a y direction) and a second boundary BNLE2 facing the first boundary BNLE1. The first boundary BNLE1 and the second boundary BNLE2 of the metal bank layer BNL may be disposed in the non-display area NDA. According to an embodiment, the first boundary BNLE1 and the second boundary BNLE2 of the metal bank layer BNL may overlap the common power supply line 16 (see FIG. 2) in a plan view. In this specification, “A and B overlap each other” represents that, in case that a plane (e.g., an xy plane) parallel to the substrate 100 in a direction perpendicular to the substrate 100 (e.g., a z-axis direction) is viewed, at least a portion of A and at least a portion of B overlap each other on a plane.

The metal bank layer BNL may define pixel openings OP corresponding to the first light-emitting diodes ED1, the second light-emitting diodes ED2, and the third light-emitting diodes ED3. For example, the first light-emitting diodes ED1 may be provided in plurality, the second light-emitting diodes ED2 may be provided in plurality, and the third light-emitting diodes ED3 may be provided in plurality. According to an embodiment, multiple first light-emitting diodes ED1 may be spaced apart from each other in the first direction (e.g., the x direction) in a first pixel row, multiple second light-emitting diodes ED2 may be spaced apart from each other in the first direction (e.g., the x direction) in a second pixel row, and multiple third light-emitting diodes ED3 may be spaced apart from each other in the first direction (e.g., the x direction) in a third pixel row. The first light-emitting diodes ED1, the second light-emitting diodes ED2, and the third light-emitting diodes ED3 may be spaced apart from one another in the second direction (for example, the y direction) intersecting the first direction (for example, the x direction). The pixel openings OP corresponding to the first light-emitting diodes ED1, the second light-emitting diodes ED2, and the third light-emitting diodes ED3 may form a matrix by being spaced apart from each other in the first direction (e.g., the x direction) and the second direction (e.g., the y direction).

The metal bank layer BNL may define holes h each extending in the first direction (e.g., the x direction). The holes h may penetrate through the metal bank layer BNL to expose an insulating layer (e.g., an inorganic bank layer 213 of FIG. 6) disposed below the metal bank layer BNL.

The holes h may be disposed between adjacent rows of the pixel openings OP. Because the pixel openings OP correspond to light-emitting diodes, the holes h may be disposed between light-emitting diode rows or pixel rows. As shown in FIG. 5, the holes h may be disposed between the first light-emitting diodes ED1 and the second light-emitting diodes ED2 and between the second light-emitting diodes ED2 and the third light-emitting diodes ED3. However, the disclosure is not limited thereto, and one or more light-emitting diode rows may be disposed between adjacent holes h. According to an embodiment, each of the first light-emitting diodes ED1, the second light-emitting diodes ED2, and the third light-emitting diodes ED3 may be disposed between adjacent holes h.

The holes h may be spaced apart from each other in the second direction (e.g., the y direction) and may be disposed parallel to each other. The holes h may be disposed between the first boundary BNLE1 and the second boundary BNLE2 of the metal bank layer BNL. For example, portions of the metal bank layer BNL outside the holes h may be connected to each other and integral with each other.

The horizontal voltage line PLh may be disposed inside the holes h. For example, the horizontal voltage line PLh may extend in the first direction (e.g., the x direction) parallel to its corresponding hole h. The horizontal voltage line PLh may have a first end E1 adjacent to the first boundary BNLE1 of the metal bank layer BNL, and a second end E2 adjacent to the second boundary BNLE2 of the metal bank layer BNL. The first end E1 and the second end E2 of the horizontal voltage line PLh may be disposed between the first boundary BNLE1 and the second boundary BNLE2 of the metal bank layer BNL.

The horizontal voltage line PLh may be separated from the metal bank layer BNL by the holes h. For example, in a plan view, the horizontal voltage line PLh may have an island shape separated from the metal bank layer BNL. For example, in a plan view, the horizontal voltage line PLh may be separated from the metal bank layer BNL, and the metal bank layer BNL may be disposed to surround the horizontal voltage line PLh.

In FIGS. 4 and 5, both of ends of the holes h and ends of the horizontal voltage lines PLh are disposed in the display area DA. However, the disclosure is not limited thereto. According to an embodiment, the ends of the holes h may be disposed between the first boundary BNLE1 and the second boundary BNLE2 of the metal bank layer BNL, in the non-display area NDA. The first end E1 and the second end E2 of the horizontal voltage line PLh may be disposed inside the hole h, in the non-display area NDA.

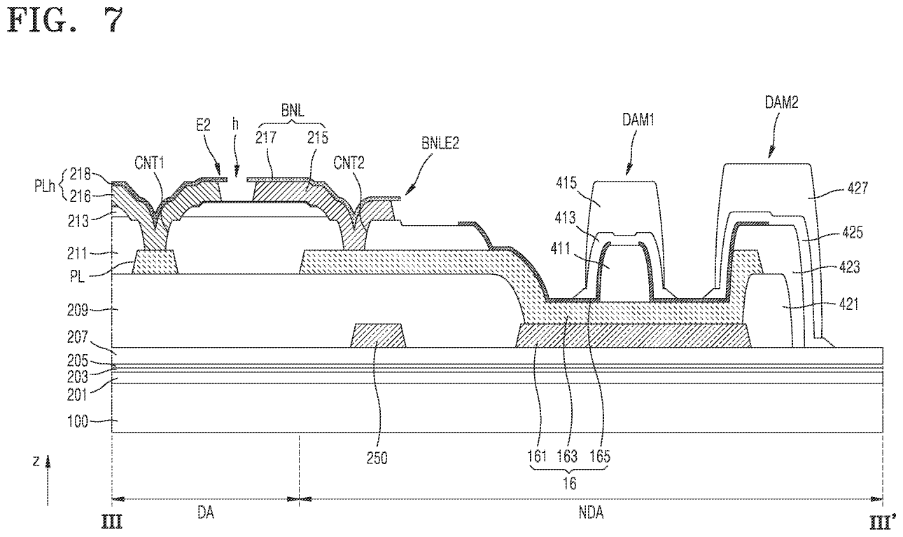

FIGS. 6 and 7 are schematic cross-sectional views of a portion of a display panel according to an embodiment. FIG. 6 schematically shows a cross-section of the display panel DP taken along line II-II′ of FIG. 5, and FIG. 7 schematically shows a cross-section of the display panel DP taken along line III-III′ of FIG. 5.

Referring to FIG. 6, multiple pixels each including a light-emitting diode and a pixel circuit electrically connected to the light-emitting diode may be disposed in the display area DA of the substrate 100. For example, a first light-emitting diode ED1, a second light-emitting diode ED2, and a third light-emitting diode ED3 may be disposed in the display area DA of the substrate 100. The first light-emitting diode ED1, the second light-emitting diode ED2, and the third light-emitting diode ED3 may emit light of different wavelengths. For example, the first light-emitting diode ED1, the second light-emitting diode ED2, and the third light-emitting diode ED3 may emit red light, green light, and blue light, respectively.

A buffer layer 201 may be disposed on an upper surface of the substrate 100. The buffer layer 201 may prevent impurities from penetrating into a semiconductor layer of the pixel circuit. The buffer layer 201 may include an inorganic insulating material, such as silicon nitride, silicon oxynitride, or silicon oxide, and may be a single layer or layers including the inorganic insulating material.

A first pixel circuit PC1, a second pixel circuit PC2, and a third pixel circuit PC3 may be arranged on the buffer layer 201. Because the first pixel circuit PC1, the second pixel circuit PC2, and the third pixel circuit PC3 are substantially the same as or similar to one another, the first pixel circuit PC1 will now be described in detail.

The first pixel circuit PC1 may include multiple transistors and a storage capacitor Cst. According to an embodiment, FIG. 6 shows that the first pixel circuit PC1 includes a thin-film transistor TFT and a storage capacitor Cst.

The thin-film transistor TFT may include a semiconductor layer Act on the buffer layer 201, a gate electrode GE overlapping a channel region of the semiconductor layer Act, a source electrode SE, and a drain electrode DE. According to an embodiment, the semiconductor layer Act may include a silicon-based semiconductor material, for example, polysilicon. According to an embodiment, the semiconductor layer Act may include a silicon-based semiconductor material, for example, a Zn oxide-based material. For example, the semiconductor layer Act may include an In—Ga—Zn—O (IGZO), In—Sn—Zn—O (ITZO), or In—Ga—Sn—Zn—O (IGTZO) semiconductor containing a metal, such as indium (In), gallium (Ga), or tin (Sn), in ZnO.

The semiconductor layer Act may include the channel region and impurity regions on both sides of the channel region. One of the impurity regions disposed on a side of the channel region may correspond to a source region, and another one of the impurity regions disposed on another side of the channel region may correspond to a drain region.

A first gate insulating layer 203 may be disposed between the semiconductor layer Act and the gate electrode GE. The first gate insulating layer 203 may include an inorganic insulating material, such as silicon oxide, silicon nitride, or silicon oxynitride, and may be a single layer or layers including the inorganic insulating material.

The gate electrode GE may include a conductive material such as molybdenum (Mo), aluminum (Al), copper (Cu), and titanium (Ti), and may be a multi-layer or single layer including the conductive material.

The storage capacitor Cst may include a lower electrode CE1 and an upper electrode CE2 overlapping each other in a plan view. According to an embodiment, the lower electrode CE1 of the storage capacitor Cst may include the gate electrode GE of the thin-film transistor TFT. For example, the gate electrode GE of the thin-film transistor TFT and the lower electrode CE1 of the storage capacitor Cst may be integral with each other.

A first interlayer insulating layer 205 may be disposed between the lower electrode CE1 and the upper electrode CE2 of the storage capacitor Cst, and a second interlayer insulating layer 207 may be disposed on the upper electrode CE2 of the storage capacitor Cst. Each of the first interlayer insulating layer 205 and the second interlayer insulating layer 207 may include an inorganic insulating material, such as silicon oxide, silicon nitride, or silicon oxynitride, and may be a single layer or layers including the inorganic insulating material.

The source electrode SE and/or the drain electrode DE may be arranged on the second interlayer insulating layer 207. According to an embodiment, one of the source electrode SE and the drain electrode DE may be omitted. The source electrode SE and/or the drain electrode DE may include a conductive material such as molybdenum (Mo), aluminum (Al), copper (Cu), and titanium (Ti), and may be a multi-layer or single layer including the conductive material. According to an embodiment, the source electrode SE and/or the drain electrode DE may be a multi-layer of titanium layer/aluminum layer/titanium layer (Ti/Al/Ti).

A first planarization layer 209 may be disposed to cover the source electrode SE and/or the drain electrode DE. According to an embodiment, the first planarization layer 209 may include an organic insulating material. The organic insulating material may include an acrylic material, benzocyclobutene e (BCB), polyimide, or hexamethyldisiloxane (HMDSO). According to an embodiment, the first planarization layer 209 may include an inorganic insulating material. The inorganic insulating material may include silicon oxide, silicon nitride, or silicon oxynitride.

A connection electrode CM may be disposed on the first planarization layer 209. The connecting electrode CM may be connected to the source electrode SE or the drain electrode DE of the thin-film transistor TFT via a contact hole that penetrates through the first planarization layer 209. The connection electrode CM may include a conductive material such as molybdenum (Mo), aluminum (Al), copper (Cu), and titanium (Ti), and may be a multi-layer or single layer including the conductive material. According to an embodiment, the connection electrode CM may be a multi-layer of titanium layer/aluminum layer/titanium layer (Ti/Al/Ti).

A second planarization layer 211 may be disposed to cover the connection electrode CM. The second planarization layer 211 may include an organic insulating material. The organic insulating material may include an acrylic material, benzocyclobutene (BCB), polyimide, or hexamethyldisiloxane (HMDSO).

The first light-emitting diode ED1, the second light-emitting diode ED2, and the third light-emitting diode ED3 may be disposed on the second planarization layer 211. The first light-emitting diode ED1 may be electrically connected to the first pixel circuit PC1, the second light-emitting diode ED2 may be electrically connected to the second pixel circuit PC2, and the third light-emitting diode ED3 may be electrically connected to the third pixel circuit PC3.

The first light-emitting diode ED1 may include a first pixel electrode 221, a first intermediate layer 231, and a first opposite electrode 241, the second light-emitting diode ED2 may include a second pixel electrode 223, a second intermediate layer 233, and a second opposite electrode 243, and the third light-emitting diode ED3 may include a third pixel electrode 225, a third intermediate layer 235, and a third opposite electrode 245. Because the first light-emitting diode ED1, the second light-emitting diode ED2, and the third light-emitting diode ED3 are substantially the same as or similar to one another, the first light-emitting diode ED1 will now be described in detail.

The first pixel electrode 221 may be electrically connected to the connection electrode CM through a contact hole that penetrates through the second planarization layer 211. In FIG. 6, the first planarization layer 209 and the second planarization layer 211 are disposed between the drain electrode DE of the thin film transistor TFT and the first pixel electrode 221. However, the disclosure is not limited thereto, and according to another embodiment, one planarization layer may be disposed between the drain electrode DE of the thin-film transistor TFT and the first pixel electrode 221. In case one planarization layer is disposed, the connection electrode CM may be omitted, and the first pixel electrode 221 may be directly connected to the drain electrode DE. According to another embodiment, three or more planarization layers may be disposed between the drain electrode DE of the thin film transistor TFT and the first pixel electrode 221, and the first pixel electrode 221 may be electrically connected to the drain electrode DE through multiple connection electrodes.

The first pixel electrode 221 may be a (semi)transparent electrode or a reflective electrode. In case that the first pixel electrode 221 is a (semi)transparent electrode, the first pixel electrode 221 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In case that the first pixel electrode 221 is a reflective electrode, a reflective layer may be formed of silver (Ag), magnesium (Mg), aluminum (Al), platinum (Pt), palladium (Pd), gold (Au), nickel (Ni), neodymium (Nd), iridium (Ir), chromium (Cr), or a compound thereof, and a layer formed of ITO, IZO, ZnO, or In₂O₃ may be formed on the reflective layer. According to an embodiment, the first pixel electrode 221 may have a structure in which an ITO layer, an Ag layer, and an ITO layer are sequentially stacked.

The inorganic bank layer 213 may be disposed on the second planarization layer 211 to cover an edge of the first pixel electrode 221. The inorganic bank layer 213 may define openings corresponding to the first pixel electrode 221, the second pixel electrode 223, and the third pixel electrode 22. The inorganic bank layer 213 may include an inorganic insulating material, such as silicon oxide, silicon nitride, or silicon oxynitride, and may be a single layer or layers including the inorganic insulating material. The inorganic bank layer 213 may prevent an arc or the like from occurring between an edge of the first pixel electrode 221 and the first opposite electrode 241 by increasing a distance between the edge of the first pixel electrode 221 and the first opposite electrode 241.

A residual sacrificial layer 212 may be disposed between the first pixel electrode 221, the second pixel electrode 223, and the third pixel electrode 225 and the inorganic bank layer 213. The residual sacrificial layer 212 may be a layer for preventing the first pixel electrode 221, the second pixel electrode 223, and the third pixel electrode 225 from being damaged by a gas or liquid used in an etching or ashing process during a manufacturing process of the display panel DP. For example, the residual sacrificial layer 212 may be a portion of a layer for protecting respective upper surfaces of the first pixel electrode 221, the second pixel electrode 223, and the third pixel electrode 225 in a dry etching process for forming the pixel openings OPs which will be described below. The residual sacrificial layer 212 may define openings that overlap the pixel openings Ops in a plan view.

The residual sacrificial layer 212 may include a material that may be selectively etched without damaging the first pixel electrode 221. For example, the residual sacrificial layer 212 may include a conductive oxide, such as indium zinc oxide (IZO) and/or indium gallium zinc oxide (IGZO).

The metal bank layer BNL may be disposed on the inorganic bank layer 213, and may define pixel openings OP overlapping the first pixel electrode 221, the second pixel electrode 223, and the third pixel electrode 225 and holes h disposed between the pixel openings OP in a plan view. The metal bank layer BNL may be formed on an entire area of the inorganic bank layer 213.

The metal bank layer BNL may include a first sub-metal layer 215 and a second sub-metal layer 217 including different metals. According to an embodiment, the second sub-metal layer 217 may be disposed on the first sub-metal layer 215. The first sub-metal layer 215 and the second sub-metal layer 217 may include metals having different etch selectivities. For example, the first sub-metal layer 215 may include aluminum (Al) or molybdenum (Mo), and the second sub-metal layer 217 may include titanium (Ti) or tantalum (Ta).

The second sub-metal layer 217 may have tips PT each extending from an upper surface of the first sub-metal layer 215 toward the center of each of the pixel openings OP. For example, a portion of the first sub-metal layer 215 disposed below the second sub-metal layer 217 may be removed in each pixel opening OP to form an undercut structure in which the second sub-metal layer 217 protrudes.

The horizontal voltage line PLh may be disposed inside the hole h. The horizontal voltage line PLh may be a portion separated from the metal bank layer BNL by removing a portion of the metal bank layer BNL, and the horizontal voltage line PLh and the metal bank layer BNL may have a same layer structure. For example, the horizontal voltage line PLh may include a first horizontal line 216 and a second horizontal line 218 disposed on the first horizontal line 216. The first horizontal line 216 and the first sub-metal layer 215 may include a same material, and the second horizontal line 218 and the second sub-metal layer 217 may include a same material. According to an embodiment, a portion of the first horizontal line 216 disposed below the second horizontal line 218 may be removed, and thus, the horizontal voltage line PLh may have an undercut structure in which the second horizontal line 218 protrudes.

The holes h may penetrate through the metal bank layer BNL, and may completely separate the horizontal voltage line PLh from the metal bank layer BNL.

The first intermediate layer 231 may be disposed on the first pixel electrode 221 in the pixel opening OP of the metal bank layer BNL. The first intermediate layer 231 may include an emission layer. The emission layer may include a low molecular or high molecular organic material that emits light of a certain color (red, green, blue, or white). According to another embodiment, the emission layer may include an inorganic material or quantum dots.

The first intermediate layer 231 may include a functional layer between the first pixel electrode 221 and the emission layer and/or between the emission layer and the first opposite electrode 241. The functional layer may include a hole transport layer (HTL), a hole injection layer (HIL), an electron transport layer (ETL), and/or an electron injection layer (EIL).

The first intermediate layer 231 may have a single stack structure including a single emission layer, or a tandem structure that is a multi-stack structure including multiple emission layers. In case that the first intermediate layer 231 has a tandem structure, a charge generation layer (CGL) may be disposed between multiple stacks.

According to an embodiment, the first intermediate layer 231 may be deposited on the entire surface of the display area DA of the substrate 100, and thus, a deposition material for forming the first intermediate layer 231 may form a first dummy intermediate layer 231P disposed on the second sub-metal layer 217. The first intermediate layer 231 and the first dummy intermediate layer 231P may include a same material. In this specification, “A and B include a same material” indicates that A and B are formed at the same time by a same process. A and B including a same material may have same film quality. The first intermediate layer 231 and the first dummy intermediate layer 231P may be separated and spaced apart from each other by the tip PT of the second sub-metal layer 217.

Similarly, the second intermediate layer 233 and the second dummy intermediate layer 233P may include a same material, and the third intermediate layer 235 and the third dummy intermediate layer 235P may include a same material. The second intermediate layer 233 and the second dummy intermediate layer 233P may be separated and spaced apart from each other by the tip PT of the second sub-metal layer 217. The third intermediate layer 235 and the third dummy intermediate layer 235P may be separated and spaced apart from each other by the tip PT of the second sub-metal layer 217.

The first opposite electrode 241 may be disposed on the first intermediate layer 231 in the pixel opening OP of the metal bank layer BNL. According to an embodiment, the first opposite electrode 241 may include a conductive material having a low work function. For example, the first opposite electrode 241 may include a (semi) transparent layer including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy of these materials. According to an embodiment, the first opposite electrode 241 may further include a layer, such as ITO, IZO, ZnO, or In₂O₃, on the (semi)transparent layer including the conductive material.

According to an embodiment, the first opposite electrode 241 may be deposited on the entire surface of the display area DA of the substrate 100, and thus, a deposition material for forming the first opposite electrode 241 may form a first dummy opposite electrode 241P disposed on the first dummy intermediate layer 231P. The first opposite electrode 241 and the first dummy opposite electrode 241P may include a same material. The first opposite electrode 241 and the first dummy opposite electrode 241P may be separated and spaced apart from each other by the tip PT of the second sub-metal layer 217.

Similarly, the second opposite electrode 243 and the second dummy opposite electrode 243P may include a same material, and the third opposite electrode 245 and the third dummy opposite electrode 245P may include a same material. The second opposite electrode 243 and the second dummy opposite electrode 243P may be separated and spaced apart from each other by the tip PT of the second sub-metal layer 217. The third opposite electrode 245 and the third dummy opposite electrode 245P may be separated and spaced apart from each other by the tip PT of the second sub-metal layer 217.

The first opposite electrode 241 may directly contact a lateral surface of the first sub-metal layer 215 defining the pixel opening OP of the metal bank layer BNL. For example, a portion of a sidewall of the first sub-metal layer 215 may be covered by the tip PT, and the first opposite electrode 241 may directly contact the sidewall of the first sub-metal layer 215 on which the first intermediate layer 231 is not formed. Accordingly, the first opposite electrode 241 may form a contact portion directly contacting the first sub-metal layer 215, and the first opposite electrode 241 may receive the common voltage ELVSS through the metal bank layer BNL.

A first capping layer 251 may be disposed on the first opposite electrode 241. The first capping layer 251 may protect the first opposite electrode 241 and increase light efficiency. A refractive index of the first capping layer 251 may be higher than a refractive index of the first opposite electrode 241. According to an embodiment, the first capping layer 251 may be a stack of layers having different refractive indexes. For example, the refractive index of the first capping layer 251 may be in a range of about 1.7 to about 1.9. The first capping layer 251 may include an organic material, and may additionally include an inorganic insulating material, such as LiF.

According to an embodiment, the first capping layer 251 may be deposited on the entire surface of the display area DA of the substrate 100, and thus, a deposition material for forming the first capping layer 251 may form a first dummy capping layer 251P disposed on the first dummy opposite electrode 241P. The first capping layer 251 and the first dummy capping layer 251P may include a same material. The first capping layer 251 and the first dummy capping layer 251P may be separated and spaced apart from each other by the tip PT of the second sub-metal layer 217.

Similarly, the second capping layer 253 and the second dummy capping layer 253P may include a same material, and the third capping layer 255 and the third dummy capping layer 255P may include a same material. The second capping layer 253 and the second dummy capping layer 253P may be separated and spaced apart from each other by the tip PT of the second sub-metal layer 217. The third capping layer 255 and the third dummy capping layer 255P may be separated and spaced apart from each other by the tip PT of the second sub-metal layer 217.

A first dummy layer DM1 may include a first dummy intermediate layer 231P, a first dummy opposite electrode 241P, and a first dummy capping layer 251P. The first dummy layer DM1 may be disposed on the second sub-metal layer 217 adjacent to a pixel opening OP of the metal bank layer BNL that corresponds to the first light-emitting diode ED1. For example, the first dummy layer DM1 may have a closed loop shape overlapping the tip PT of the second sub-metal layer 217 in a plan view.

A second dummy layer DM2 may include a second dummy intermediate layer 233P, a second dummy opposite electrode 243P, and a second dummy capping layer 253P. The second dummy layer DM2 may be disposed on the second sub-metal layer 217 adjacent to a pixel opening OP of the metal bank layer BNL that corresponds to the second light-emitting diode ED2. A portion 312P of a first clad layer 312 may remain between the second dummy layer DM2 and the metal bank layer BNL. A third dummy layer DM3 may include a third dummy intermediate layer 235P, a third dummy opposite electrode 245P, and a third dummy capping layer 255P. The third dummy layer DM3 may be disposed on the second sub-metal layer 217 adjacent to a pixel opening OP of the metal bank layer BNL that corresponds to the third light-emitting diode ED3. A portion 314P of a second clad layer 314 may remain between the third dummy layer DM3 and the metal bank layer BNL.

A first inorganic encapsulation layer 311 may be formed on the first capping layer 251 to seal the first light-emitting diode ED1. The first inorganic encapsulation layer 311 may include silicon nitride or silicon oxynitride.

The first inorganic encapsulation layer 311 may have a relatively excellent step coverage, and thus may directly contact a lower surface of the tip PT of the second sub-metal layer 217 and the lateral surface of the first sub-metal layer 215 to thereby form an inorganic contact area that completely surrounds the first light-emitting diode ED1. Accordingly, the first inorganic encapsulation layer 311 may reduce or block a path through which impurities permeate into the first light-emitting diode ED1.

Similarly, a second inorganic encapsulation layer 313 for sealing the second light-emitting diode ED2 may be disposed on the second capping layer 253, and a third inorganic encapsulation layer 315 for sealing the third light-emitting diode ED3 may be disposed on the third capping layer 255.

The first inorganic encapsulation layer 311, the second inorganic encapsulation layer 313, and the third inorganic encapsulation layer 315 may be spaced apart from one another. For example, the first inorganic encapsulation layer 311 may be patterned in an island shape to cover the first light-emitting diode ED1, the second inorganic encapsulation layer 313 may be patterned in an island shape to cover the second light-emitting diode ED2, and a third inorganic encapsulation layer 315 may be patterned in an island shape to cover the third light-emitting diode ED3.

The first clad layer 312 may be disposed to cover an end of the first dummy layer DM1 positioned between the first inorganic encapsulation layer 311 and the metal bank layer BNL. The first clad layer 312 may prevent impurities from permeating into the first light-emitting diode ED1 through the first dummy layer DM1. The first clad layer 312 may include silicon nitride or silicon oxynitride.

Similarly, the second clad layer 314 may be disposed to cover an end of the second dummy layer DM2, and a third clad layer 316 may be disposed to cover an end of the third dummy layer DM3.

An organic encapsulation layer 320 may be disposed on the first inorganic encapsulation layer 311, the second inorganic encapsulation layer 313, and the third inorganic encapsulation layer 315. The organic encapsulation layer 320 may provide a flat base surface to components disposed on an upper portion of the organic encapsulation layer 320. The organic encapsulation layer 320 may include a polymer-based material. Examples of the polymer-based material may include an acrylic resin, an epoxy-based resin, polyimide, and polyethylene.

A fourth inorganic encapsulation layer 330 may be disposed on the organic encapsulation layer 320. The fourth inorganic encapsulation layer 330 may include at least one inorganic material such as aluminum oxide, titanium oxide, tantalum oxide, hafnium oxide, zinc oxide, silicon oxide, silicon nitride, and silicon oxynitride.

Referring to FIG. 7, a buffer layer 201, a first gate insulating layer 203, a first interlayer insulating layer 205, a second interlayer insulating layer 207, a first planarization layer 209, and a second planarization layer 211 may each extend from the display area DA to the non-display area NDA.

Signal lines 250 may be arranged between the second interlayer insulating layer 207 and the first planarization layer 209. The signal lines 250 may include a conductive material such as molybdenum (Mo), aluminum (Al), copper (Cu), and titanium (Ti), and may each be a multi-layer or single layer including the conductive material.

Driving voltage lines PL may be arranged between the first planarization layer 209 and the second planarization layer 211. The driving voltage lines PL may include a conductive material such as molybdenum (Mo), aluminum (Al), copper (Cu), and titanium (Ti), and may each be a multi-layer or single layer including the conductive material.

A common power supply line 16 may be disposed in the non-display area NDA. The common power supply line 16 may be disposed parallel to the edge of the substrate 100, and may surround at least a portion of the display area DA in a plan view. The common power supply line 16 may include a first line 161, a second line 163 disposed on the first line 161, and a third line 165 disposed on the second line 163.

The first line 161 may be disposed on the second interlayer insulating layer 207 and may have an inner edge covered by the first planarization layer 209. The second line 163 may be disposed between the first planarization layer 209 and the second planarization layer 211, and may be connected to the first line 161 outside the first planarization layer 209. The first line 161 and the second line 163 may include a conductive material such as molybdenum (Mo), aluminum (Al), copper (Cu), and titanium (Ti), and may each be a multi-layer or single layer including the conductive material. According to an embodiment, the first line 161 and the source electrode SE and/or the drain electrode DE may include a same material, and the second line 163 and the connection electrode CM may include a same material.

The third line 165 may be disposed on the second planarization layer 211, and may be connected to the second line 163 outside the second planarization layer 211. The third line 165 and the first pixel electrode 221 may include a same material. According to an embodiment, the third line 165 may have a structure in which an ITO layer, an Ag layer, and an ITO layer are sequentially stacked.

The metal bank layer BNL may extend into the non-display area NDA and may be disposed to overlap the common power supply line 16 in a plan view. For example, a second boundary BNLE2 of the metal bank layer BNL may be disposed to overlap the common power supply line 16 in a plan view. The first sub-metal layer 215 of the metal bank layer BNL may be connected to the second line 163 of the common power supply line 16 through a second contact portion CNT2 that penetrates through the second planarization layer 211. Accordingly, the metal bank layer BNL may receive the common voltage ELVSS from the common power supply line 16. According to an embodiment, the second contact portion CNT2 may be continuously arranged to overlap the common power supply line 16 and surround at least a portion of the display area DA in a plan view.

The metal bank layer BNL and the horizontal voltage line PLh may be separated from the metal bank layer BNL by the hole h. For example, the second end E2 of the horizontal voltage line PLh may be disposed inside the hole h. The horizontal voltage line PLh may be electrically connected to the driving voltage line PL through the first contact portion CNT1 penetrating through the second planarization layer 211 and the inorganic bank layer 213. As shown in FIG. 2, because the driving voltage line PL may extend over the display area DA in the second direction (e.g., the y direction) and the horizontal voltage line PLh extends over the display area DA in the first direction (e.g., the x direction), the driving voltage line PL and the horizontal voltage line PLh may form a mesh shape in a plan view. Accordingly, a luminance difference according to locations of pixels caused by a resistance of the driving voltage line PL may be reduced.

A first dam DAM1 and a second dam DAM2 may be spaced apart from each other on the non-display area NDA of the substrate 100. According to an embodiment, referring to FIG. 7, the first dam DAM1 may include a 1-1^{st} organic layer 411, a first inorganic layer 413, and a 1-2^{nd} organic layer 415, and the second dam DAM2 may include a 2-1^{st} organic layer 421, an 2-2^{nd} organic layer 423, a second inorganic layer 425, and a 2-3^{rd} organic layer 427. However, the disclosure is not limited thereto. Layers constituting the first dam DAM1 and/or the second dam DAM2 may be added, or may be partially omitted.

The first dam DAM1 may be disposed to overlap the common power supply line 16 in a plan view. For example, the 1-1^{st} organic layer 411 of the first dam DAM1 may be disposed on the second line 163 of the common power supply line 16. The third line 165 of the common power supply line 16 may be disposed to cover at least a portion of the 1-1^{st} organic layer 411.

The 1-1^{st} organic layer 411 may include an organic insulating material. The organic insulating material may include an acrylic material, benzocyclobutene (BCB), polyimide, or hexamethyldisiloxane (HMDSO). According to an embodiment, the 1-1^{st} organic layer 411 and the second planarization layer 211 may include a same material.

The first inorganic layer 413 may be disposed on the 1-1^{st} organic layer 411. The third line 165 of the common power supply line 16 may be disposed between the first inorganic layer 413 and the 1-1^{st} organic layer 411. The first inorganic layer 413 may include an inorganic insulating material, such as silicon oxide, silicon nitride, or silicon oxynitride, and may be a single layer or layers including the inorganic insulating material. According to an embodiment, the first inorganic layer 413 and the inorganic bank layer 213 may include a same material.

The 1-2^{nd} organic layer 415 may be disposed on the first inorganic layer 413. The 1-2^{nd} organic layer 415 may include an organic insulating material. The organic insulating material may include an acrylic material, benzocyclobutene (BCB), polyimide, or hexamethyldisiloxane (HMDSO).

The second dam DAM2 may be disposed to cover an outer edge of the common power supply line 16. For example, the 2-1^{st} organic layer 421 of the second dam DAM2 may cover an outer edge of the first line 161 of the common power supply line 16, and the 2-2^{nd} organic layer 423 may cover an outer edge of the second line 163 of the common power supply line 16. An outer edge of the third line 165 of the common power supply line 16 may be disposed between the 2-2^{nd} organic layer 423 and the second inorganic layer 425.

The 2-1^{st} organic layer 421 may include an organic insulating material. The organic insulating material may include an acrylic material, benzocyclobutene (BCB), polyimide, or hexamethyldisiloxane (HMDSO). According to an embodiment, the 2-1^{st} organic layer 421 and the first planarization layer 209 may include a same material.

The 2-2^{nd} organic layer 423 may be disposed on the 2-1^{st} organic layer 421 to cover the 2-1^{st} organic layer 421. The outer edge of the second line 163 of the common power supply line 16 may be disposed on the 2-1^{st} organic layer 421, and the 2-2^{nd} organic layer 423 may cover the outer edge of the second line 163. The 2-2^{nd} organic layer 423 may include an organic insulating material. The organic insulating material may include an acrylic material, benzocyclobutene (BCB), polyimide, or hexamethyldisiloxane (HMDSO). According to an embodiment, the 2-2^{nd} organic layer 423 and the second planarization layer 211 may include a same material.

The second inorganic layer 425 may be disposed on the 2-2^{nd} organic layer 423 to cover the 2-2^{nd} organic layer 423. For example, the second inorganic layer 425 may be disposed to cover the outer edge of the third line 165 of the common power supply line 16 positioned on the 2-2^{nd} organic layer 423. The second inorganic layer 425 may include an inorganic insulating material, such as silicon oxide, silicon nitride, or silicon oxynitride, and may be a single layer or layers including the inorganic insulating material. According to an embodiment, the second inorganic layer 425 and the inorganic bank layer 213 may include a same material. The first inorganic layer 413 and the second inorganic layer 425 may be formed simultaneously during forming of the inorganic bank layer 213.

A 2-3^{rd} organic layer 427 may be disposed on the second inorganic layer 425. The 2-3^{rd} organic layer 427 may include an organic insulating material. The organic insulating material may include an acrylic material, benzocyclobutene (BCB), polyimide, or hexamethyldisiloxane (HMDSO).

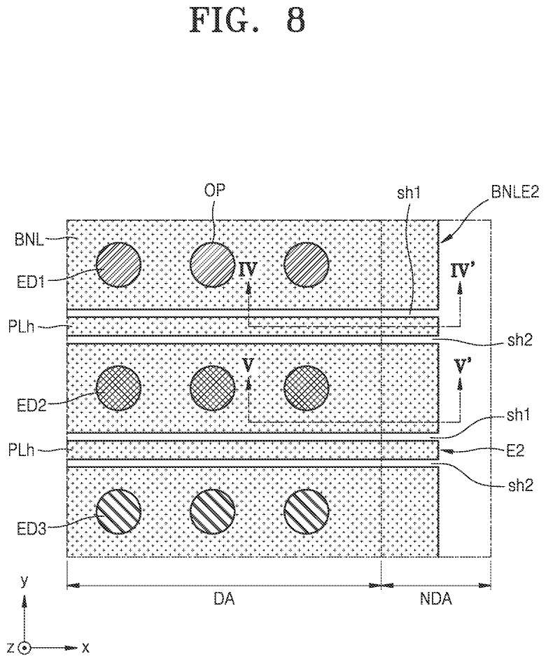

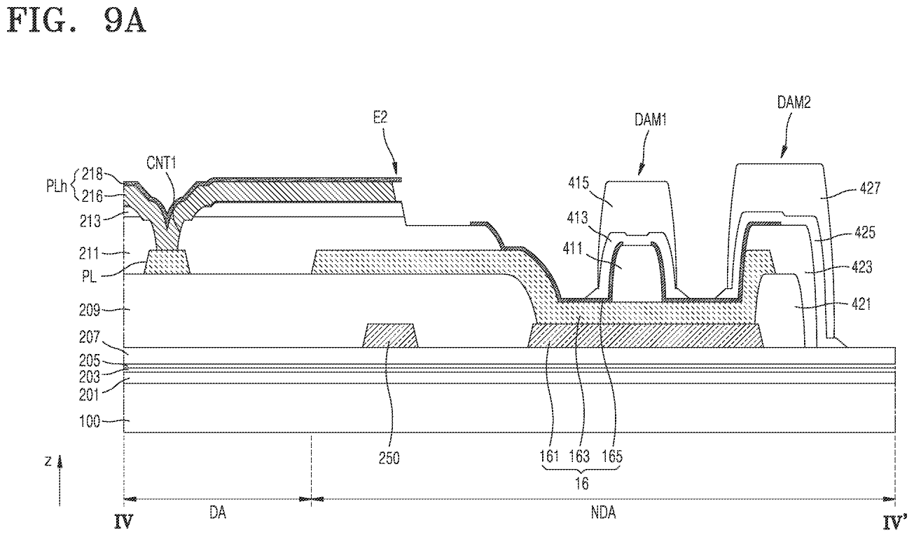

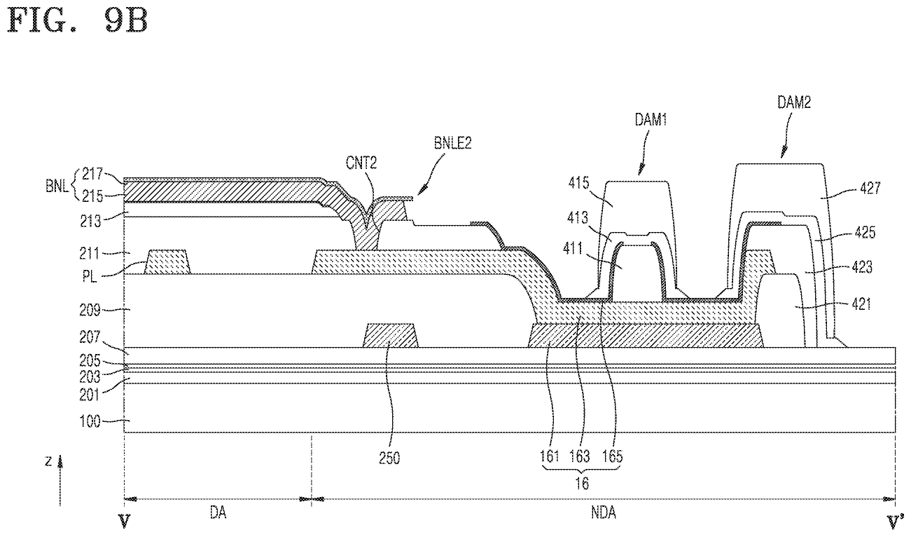

FIG. 8 is a schematic plan view of a portion of a display panel according to an embodiment, and FIGS. 9A and 9B are schematic cross-sectional views of a portion of a display apparatus according to an embodiment. FIG. 8 is similar to FIG. 5, but is different from FIG. 5 in that the end of the horizontal voltage line PLh coincides with the second boundary BNLE2. Descriptions of components shown in FIG. 8 that are the same as or similar to those shown in FIG. 5 will now be omitted, and a description will now be made focusing on the differences.

Referring to FIG. 8, the metal bank layer BNL may define pixel openings OP, and a first sub-hole sh1 spaced apart from the pixel openings OP and extending in the first direction (e.g., the x direction) and a second sub-hole sh2 extending in the first direction (e.g., the x direction) and spaced apart from the first sub hole sh1 in the second direction (e.g., the y direction).

The first sub-hole sh1 and the second sub-hole sh2 may extend over the display area DA from the first boundary BNLE1 (see FIG. 4) of the metal bank layer BNL to the second boundary BNLE2 of the metal bank layer BNL. For example, in a plan view, the metal bank layer BNL may be divided into multiple portions by the first sub-hole sh1 and the second sub-hole sh2.

In a plan view, the horizontal voltage line PLh may be disposed between the first sub-hole sh1 and the second sub-hole sh2. According to an embodiment, the horizontal voltage line PLh may have the first end E1 (see FIG. 4) and the second end E2 facing the first end E1, the first end E1 may colinear with the first boundary BNLE1 of the metal bank layer BNL, and the second end E2 may colinear with the second boundary BNLE2 of the metal bank layer BNL.

Referring to FIGS. 9A and 9B, a buffer layer 201, a first gate insulating layer 203, a first interlayer insulating layer 205, a second interlayer insulating layer 207, a first planarization layer 209, and a second planarization layer 211 may each extend from the display area DA to the non-display area NDA.

The signal lines 250 may be disposed between the second interlayer insulating layer 207 and the first planarization layer 209, and the driving voltage lines PL may be disposed between the first planarization layer 209 and the second planarization layer 211. As described above with reference to FIG. 2, the driving voltage line PL may extend over the display area DA in the second direction (e.g., the y direction).

The horizontal voltage line PLh may be disposed between the first sub-hole sh1 and the second sub-hole sh2. The horizontal voltage line PLh may be a portion separated from the metal bank layer BNL by removing a portion of the metal bank layer BNL, and horizontal voltage line PLh and the metal bank layer BNL may have a same layer structure. For example, the horizontal voltage line PLh may include a first horizontal line 216 and a second horizontal line 218 disposed on the first horizontal line 216. The first horizontal line 216 and the first sub-metal layer 215 may include a same material, and the second horizontal line 218 and the second sub-metal layer 217 may include a same material. According to an embodiment, a portion of the first horizontal line 216 disposed below the second horizontal line 218 may be removed, and thus, the horizontal voltage line PLh may have an undercut structure in which the second horizontal line 218 protrudes.

The horizontal voltage line PLh may be connected to the driving voltage line PL through the first contact portion CNT1 penetrating through the second planarization layer 211 and the inorganic bank layer 213. For example, the first horizontal line 216 of the horizontal voltage line PLh may directly contact the driving voltage line PL through the first contact part CNT1. Because the horizontal voltage line PLh extends in the first direction (e.g., the x direction), the driving voltage line PL and the horizontal voltage line PLh may form a mesh shape in which they intersect each other, in a plan view.

A portion of the horizontal voltage line PLh may overlap the common power supply line 16 in a plan view. For example, as shown in FIG. 9A, the second end E2 of the horizontal voltage line PLh may be disposed on the common power supply line 16.

The first sub-metal layer 215 of the metal bank layer BNL may be connected to the second line 163 of the common power supply line 16 through the second contact portion CNT2 that penetrates through the second planarization layer 211. For example, the first sub-metal layer 215 of the metal bank layer BNL may directly contact the second line 163 of the common power supply line 16 through the second contact portion CNT2. The second boundary BNLE2 of the metal bank layer BNL may overlap the common power supply line 16 in a plan view. For example, the second boundary BNLE2 of the metal bank layer BNL may be disposed on the common power supply line 16.

As the horizontal voltage lines PLh according to embodiments may be connected to the driving voltage lines PL in a horizontal direction, a luminance difference according to pixels' locations caused by the resistance of the driving voltage lines PL may be reduced. Because the horizontal voltage lines PLh and the metal bank layer BNL are formed through a same process, an additional process or layer for forming the horizontal voltage lines PLh is not necessary.

According to an embodiment as described above, a display apparatus for displaying a high-quality image by reducing a luminance difference according to pixels' locations may be realized. However, the scope of the disclosure is not limited thereto.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
a substrate comprising a display area in which a plurality of pixels are arranged and a non-display area disposed adjacent to the display area;
a pixel electrode disposed on the display area of the substrate;
a metal bank layer disposed in the display area and the non-display area and defining a pixel opening exposing a portion of the pixel electrode and a hole spaced apart from the pixel opening and extending in a first direction; and
a horizontal voltage line disposed in the display area inside the hole in a plan view.

2. The display apparatus of claim 1, wherein
the metal bank layer comprises a first sub-metal layer and a second sub-metal layer disposed on the first sub-metal layer, and
the second sub-metal layer has a tip extending from an upper surface of the first sub-metal layer toward a center of the pixel opening.

3. The display apparatus of claim 2, further comprising:
an intermediate layer disposed on the pixel electrode in the pixel opening; and
an opposite electrode disposed on the intermediate layer in the pixel opening.

4. The display apparatus of claim 3, wherein the opposite electrode is directly connected to the first sub-metal layer.

5. The display apparatus of claim 2, further comprising:
a common power supply line disposed in the non-display area and surrounding at least a portion of the display area in a plan view,
wherein the first sub-metal layer is directly connected to the common power supply line.

6. The display apparatus of claim 5, wherein
the metal bank layer has a first boundary and a second boundary facing the first boundary, and
the first boundary and the second boundary overlap the common power supply line in a plan view.

7. The display apparatus of claim 6, wherein
the horizontal voltage line has a first end and a second end, and
the first end and the second end of the horizontal voltage line are disposed between the first boundary and the second boundary of the metal bank layer.

8. The display apparatus of claim 2, wherein
the horizontal voltage line comprises a first horizontal line and a second horizontal line disposed on the first horizontal line,
the first horizontal line and the first sub-metal layer comprise a same material, and
the second horizontal line and the second sub-metal layer comprise a same material.

9. The display apparatus of claim 1, further comprising:
a driving voltage line disposed between the substrate and the horizontal voltage line and extending in a second direction intersecting the first direction,
wherein the horizontal voltage line is electrically connected to the driving voltage line.

10. The display apparatus of claim 9, wherein
the driving voltage line includes a plurality of driving voltage lines,
the horizontal voltage line includes a plurality of horizontal voltage lines, and
in a plan view, the plurality of driving voltage lines and the plurality of horizontal voltage lines form a mesh shape.

11. A display apparatus comprising:
a substrate comprising a display area in which a plurality of pixels are arranged and a non-display area disposed adjacent to the display area;
a pixel electrode disposed on the display area of the substrate;
a metal bank layer disposed in the display area and the non-display area and defining a pixel opening exposing a portion of the pixel electrode and a first sub-hole and a second sub-hole spaced apart from the pixel opening, each of the first sub-hole and the second sub-hole extending in a first direction; and
a horizontal voltage line disposed in the display area and the non-display area between the first sub-hole and the second sub-hole in a plan view.

12. The display apparatus of claim 11, wherein
the metal bank layer comprises a first sub-metal layer and a second sub-metal layer disposed on the first sub-metal layer, and
the second sub-metal layer has a tip extending from an upper surface of the first sub-metal layer toward a center of the pixel opening.

13. The display apparatus of claim 12, further comprising:
an intermediate layer disposed on the pixel electrode in the pixel opening; and
an opposite electrode disposed on the intermediate layer in the pixel opening.

14. The display apparatus of claim 13, wherein the opposite electrode is directly connected to the first sub-metal layer.

15. The display apparatus of claim 12, further comprising:
a common power supply line disposed in the non-display area and surrounding at least a portion of the display area in a plan view,
wherein the first sub-metal layer is directly connected to the common power supply line.

16. The display apparatus of claim 15, wherein
the metal bank layer has a first boundary and a second boundary facing the first boundary, and
the first boundary and the second boundary overlap the common power supply line in a plan view.

17. The display apparatus of claim 16, wherein
the horizontal voltage line has a first end and a second end,
the first end of the horizontal voltage line is colinear with the first boundary of the metal bank layer, and
the second end of the horizontal voltage line is colinear with the second boundary of the metal bank layer.

18. The display apparatus of claim 12, wherein
the horizontal voltage line comprises a first horizontal line and a second horizontal line disposed on the first horizontal line,
the first horizontal line and the first sub-metal layer comprise a same material, and
the second horizontal line and the second sub-metal layer comprise a same material.

19. The display apparatus of claim 11, further comprising:
a driving voltage line disposed between the substrate and the horizontal voltage line and extending in a second direction intersecting the first direction,
wherein the horizontal voltage line is electrically connected to the driving voltage line.

20. The display apparatus of claim 19, wherein
the driving voltage line includes a plurality of driving voltage lines,
the horizontal voltage line include a plurality of horizontal voltage lines, and
in a plan view, the plurality of driving voltage lines and the plurality of horizontal voltage lines form a mesh shape.
